(19) United States
(12) Patent Application Publication
(10) Pub. No.: US 2018/0364285 A1
(43) Pub. Date: Dec. 20, 2018

(54) VOLTAGE REGULATOR WITH TIME-AWARE CURRENT REPORTING

(71) Applicants: Anatoly Gelman, San Diego, CA (US); Taner Dosluoglu, New York, NY (US)

(72) Inventors: Anatoly Gelman, San Diego, CA (US); Taner Dosluoglu, New York, NY (US)

(21) Appl. No.: 16/009,059

(22) Filed: Jun. 14, 2018

Related U.S. Application Data
(60) Provisional application No. 62/519,354, filed on Jun. 14, 2017.

(51) Int. Cl. G01R 19/25; H02M 3/158

(52) U.S. Cl. CPC G01R 19/25; H02M 1/00; H02M 3/158

(57) ABSTRACT

Systems and methods for providing an indication of an output current of a voltage regulator applied to a load at an indicated time to a processor. An indication of the output current of a voltage regulator is determined in response to a clock signal received from a clock source and a frame number of a frame is determined from the clock source. The indication of the current output and the frame number of the associated frame are provided to the processor.

### CROSS REFERENCED APPLICATIONS

This application claims priority to U.S. Provisional Patent Application No. 62/519,354 entitled “Voltage Regulator with Time-Aware Current Reporting” filed Jun. 14, 2017, which is hereby incorporated by reference in its entirety as if set forth herewith.

### BACKGROUND OF THE INVENTION

The present invention relates generally to voltage regulation for integrated circuits, and more particularly to voltage regulator current reporting.

Integrated circuits generally require provision of supply voltage within particular parameters during operation. The provision of such supply voltage may face many complexities. For example, semiconductor chips including the integrated circuits may have different portions that require power at the same or different times, different portions may require power within different parameters, and some portions may consume different amounts of power at different times.

Further complicating matters, some devices may be powered by batteries having relatively small capacities. The devices themselves, however, at least at various times, may require large amounts of power at various times (and possibly require smaller to little amounts of power at other times). In such devices it may be beneficial to provide power only when needed, for example in order to lengthen effective battery life between charging. It may also be beneficial to restrict provision of power at various times, for example to avoid possible thermal related problems with integrated circuit operation.

Unfortunately, for example given the complexities of possible operating states that may be available for integrated circuits, for example smartphone processors, it may be difficult to know during design phases, of hardware and/or software, how voltage regulation or integrated circuitry operational speeds should be adjusted in view of power requirements and usage. Moreover, a host processor, which may be involved in determining voltage levels or integrated circuitry operation speeds, may not have access to accurate information regarding power usage, past or present.

### BRIEF SUMMARY OF THE INVENTION

Some embodiments provide provision of information regarding current supplied to a load and an indication of time at which the current was supplied to the load. In some embodiments a voltage regulator stores an indication of current provided to the load and also stores indication as to when that current was provided to the load, with the information made available to a processor. In some embodiments the indication of current provided to the load is an instantaneous snapshot of current consumption, in some embodiments the indication of current is averaged over a predetermined period of time. In some embodiments the indication as to when current was provided to the load is an indication of a frame during which the current was provided to the load. In some embodiments the frame has a duration of a plurality of clock cycles of a load. In some embodiments the frame has a duration equal to between 5 and 2000 clock cycles of the load. In some embodiments the frame has time boundaries accurate to within a time between 5 and 20 clock cycles of the load, and in some embodiments within a time less than 20 clock cycles of the load, and in some embodiments within a time less than 10 clock cycles of the load.

Some embodiments precisely associate an indication of consumed current at point of load with time. In some embodiments a voltage regulator performs the precise association. In some embodiments a host processor may read the indication of consumed current at point of load and time from the voltage regulator when requested by the host processor. In some embodiments the voltage regulator provides the host processor the indication of consumed current at point of load and time at predetermined intervals. In some embodiments the indication of consumed current and time is generated repeatedly, forming a current profile. In some embodiments precisely associating indications of consumed current at point of load with time, over time, comprises current profiling. In some embodiments the host processor performs current profiling. In some embodiments the voltage regulator performs current profiling.

One aspect of the invention provides a method of providing voltage regulator time aware output current indications to a host processor, comprising: determining an indication of voltage regulator output current; determining a period of time during which the indication of voltage regulator output current was determined; storing in memory of the voltage regulator the indication of voltage regulator output current in association with an indication of the period of time during which the indication of voltage regulator output current was determined; and providing to the host processor the indication of voltage regulator output current and the indication of the period of time during which the indication of voltage regulator output current was determined.

Another aspect of the invention provides a system for providing to a host processor an indication of an output current of a voltage regulator supplied to a load, the system comprising: a current meter configured to determine an indication of the output current of the voltage regulator supplied to a load; a current register configured to store the indication of the output current, the current register readable by the host processor; a counter to count a number of cycles of a clock signal of a voltage regulator at which a frame number for the voltage regulator should be incremented; and a frame number register configured to store the frame number of a frame associated with the indication of the output current, the frame number register readable by the host processor.

In some aspects of the invention, a time aware current output of a voltage regulator may be provided to a processor. A clock signal is received from a clock source. A frame number for a frame is determined based on the clock signal and an indication of an output current of the voltage regulator applied to a load is determined in response to receiving the clock signal. The indication of the output current and the frame number are provided to the processor.

In some embodiments, the frame number may be stored in a frame number register. The indication of the output current may be stored in a current register in many embodiments. In a number of embodiments, an interrupt signal based on the clock signal and transmitted to the processor to indicate to the processor that the indication of the output current and the frame number may be read from the frame number and current registers.

In some embodiments, the indication of the output current may be an average of the output current applied to the load by the voltage regulator over a predetermined period of time. In some other embodiments, the indication of the output current applied to the load maybe a measurement of the output current a specific time.

In some embodiments, the clock source may be an on-chip oscillator. In some other embodiments, the clock source may be an external clock.

In some embodiments, each frame has a duration of a predetermined number of clock cycle of the load.

In some aspects of the invention, a system for providing an indication of an output current of a voltage regulator applied to a load to a processor includes a current meter and a frame number register. The current meter determines an indication of the output current of the voltage regulator applied to a load in response to a clock signal received from a clock source and provides the indication to the processor and the frame number register stores a frame number of a frame associated with the indication of the output current that is read by the processor to provide the frame number of the processor, the frame number being determined based upon the clock signal received from the clock source.

In some embodiments, a current level register may store the indication of the output voltage determined by the current meter and is read by the processor to provide the indication of the output current to the processor. In many embodiments, a time counter may receive the clock signal from the clock source and generate a time signal provided to at least one of the frame number register and the current level register. In a number of embodiments, interrupt logic may receive the time signal from the time counter and generate an interrupt signal provided to the processor. The processor may read the frame number register and the current level register in response to receiving the interrupt signal.

In some embodiments, the indication of the output current may be an average of the output current applied to the load over a predetermined period of time. In some other embodiments, the indication of the output current applied to the load may be a measurement of the output current at a specific time.

In some embodiments, the clock source may be an on-chip oscillator. In some other embodiments, the clock source may be an external clock.

In some embodiments, each frame may have a duration of a predetermined number of clock cycles of the load.

These and other aspects of the invention are more fully comprehended upon review of this disclosure.

### BRIEF DESCRIPTION OF THE FIGURES

FIG. 1 is a block diagram of an example voltage regulator with time aware current metering in accordance with aspects of the invention.

FIG. 2 is flow diagram of a process for associating an indication of current provided to a load with a time.

FIG. 3 is flow diagram of a further process for associating an indication of current provided to a load with a time.

FIG. 4 is a semi-schematic, semi-block diagram of a voltage regulator including example current metering circuitry.

### DETAILED DESCRIPTION

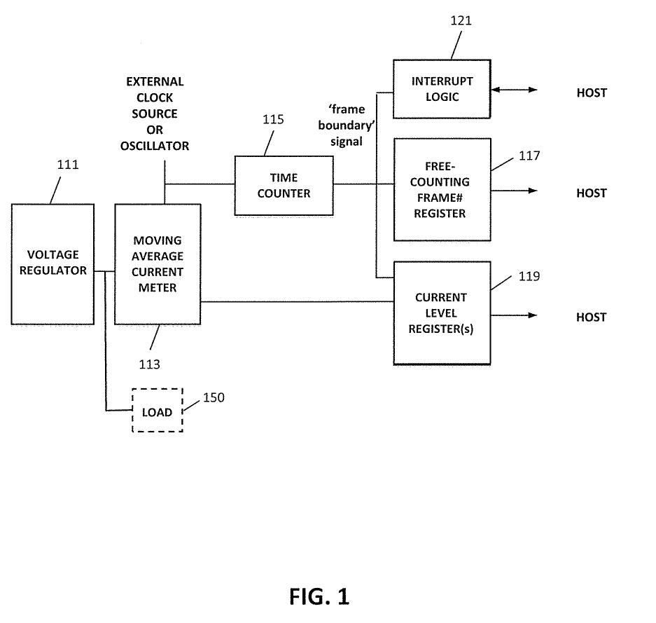

FIG. 1 is a block diagram of an example voltage regulator with time aware current metering in accordance with aspects of the invention. The voltage regulator with time aware current metering can be considered as, or implemented as, a voltage regulator block in various embodiments. In FIG. 1, voltage regulation circuitry 111, e.g. what often may be considered a voltage regulator, supplies regulated voltage to a load 150 (shown in dashed form, as the load itself is not part of the voltage regulator with time aware current metering). The voltage regulator may be, for example, a switching voltage regulator, and may be in various embodiments a buck type, boost type, or buck-boost type voltage regulator.

A current meter 113 determines an indication of current provided to the load. In some embodiments the current meter may include a resistor, preferably small, in-line with the load, with circuitry, for example an analog-to-digital circuit (ADC) determining a voltage drop across the resistor. In other embodiments other circuitry, for example circuitry that does not include an in-line resistor, may be used. In some embodiments the current meter obtains an indication of current provided to the load on an essentially instantaneous, or single point in time (during a single clock period, or within just a few clock cycles) basis. In other embodiments, and as illustrated in FIG. 1, the current meter obtains an indication of current provided to the load over a period of time, and may do so using a moving average over different periods of time, with the different periods of time overlapping in some embodiments. As the current meter determines the indication of current between the output of the voltage regulator and the load, the indication of current may be considered to be at the point of load.

In the embodiment of FIG. 1, the current meter is operated at a clock rate of a clock signal, which may be derived from an on-chip oscillator or an external clock input. The clock signal may, for example, be a 100 MHz clock signal, while the load may be operated by a clock signal that may go into the low GHz range, for example.

A time counter 115 also receives the clock signal. The time counter counts from an initial value up to a terminal count value, and then restarts counting from the initial value. In some embodiments the terminal count value is programmable. Upon reaching the terminal count value, the time counter produces a frame boundary signal, indicating a time boundary of a frame.

The frame boundary signal is provide to a frame counting frame number register 117 and a current level register 119. The frame counting register increments a frame count value on receipt of the frame boundary signal. In some embodiments the current level register stores the indication of current from the current meter on receipt of the frame boundary signal. In some embodiments the current level register stores the indication of current on a periodic basis, at a rate greater than a rate of occurrence of the frame boundary signal. In some embodiments the current level stores such indications of current in a subset of registers of the current level register, transitioning to use of a different subset of registers on occurrence of the frame boundary signal.

The frame boundary signal is also provide to interrupt logic 121, in the embodiment illustrated in FIG. 1. The interrupt logic, in some embodiments, is used to provide an interrupt request to a host processor (not shown), for example on receipt of the frame boundary signal. The interrupt request may indicate to the host processor that current and time information is available to be read from the voltage regulator. In some embodiments, however, the host processor may otherwise determine when to read the current and time information, for example by using a polling or other method.

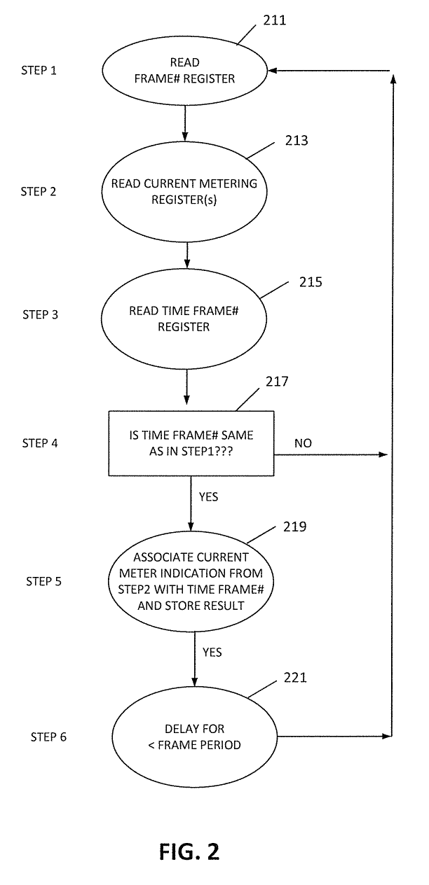

FIG. 2 is flow diagram of a process for associating an indication of current provided to a load with a time, for example as indicated by a frame number. In some embodiments the process provides for current profiling. In some embodiments the process is performed by a host processor. In some embodiments the process is used by the processor to perform a polling method for reading information relating current provided to load and time the current is provided to the load. In some embodiments the process may be performed by a voltage regulator having current profiling related circuitry.

In block 211 the process reads a frame number from a frame number register. The frame number is indicative of a time. The frame number register is a register, or other memory or storage element(s) storing the frame number. The frame number stored in the frame number register, for example, may be modified over time, for example to indicate a passage of time. In some embodiments the frame number and/or the frame number register are as discussed with respect to FIG. 1.

In block 213 the process reads an indication of current provided to a load from a current metering register. The current metering register, similar to the frame number register, is a register, or other memory or storage element(s) storing the indication of current provided to the load. The indication of current stored in the current metering register may be modified over time, for example to reflect changes in current provided to the load. In some embodiment the indication of current provided to the load and/or the current metering register are as discussed with respect to FIG. 1.

In block 215 the process again reads a frame number from the frame number register. If the frame number in the frame number register has not changed since the frame number was read in block 211, then the frame number read in block 215 will be the same as the frame number read in block 211. If the frame number stored in the frame number register has changed however, then the two frame numbers read, in block 211 and in block 215, will be different. In some embodiments the process performs the operation of block 215 (and block 217) in order to avoid potential errors in associating frame numbers and indications of current due to interruptions to execution of the process of FIG. 2, which may occur, for example, if a host processor performing the operation is required to perform other higher priority tasks while performing the process of FIG. 2.

In block 217 the process determines if the frame number read in block 215 is the same as the frame number read in block 211. If not, the process proceeds back to operations of block 211. If so, however, the process continues to block 219.

In block 219 the process associates the indication of current provided to the load, read in block 213, with the frame number read in blocks 211 and 215, and stores such information. In various embodiments the process may stores the indication of current and frame number in a table, for example, or in some other data structure.

In block 221 the process delays for a period of time. In some embodiments the process delays for a period of time less than an expected frame period. In some embodiments the process delays for a period of time equal to an expected frame period. In some embodiments the process delays for some other period of time.

After delaying for the period of time, the process returns to operations of block 211.

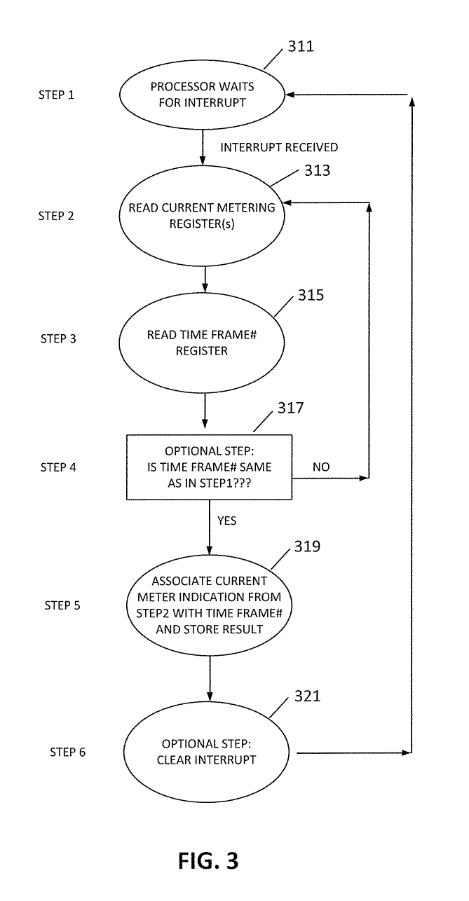

FIG. 3 is flow diagram of a further process for associating an indication of current provided to a load with a time, for example as indicated by a frame number. In some embodiments the process provides for current profiling. In some embodiments the process is performed by a host processor. In some embodiments the process is used by the processor to perform an interrupt driven method for reading information relating current provided to load and time the current is provided to the load. In some embodiments the process may be performed by a voltage regulator having current profiling related circuitry.

In block 311 the process waits for receipt of an interrupt request signal. In some embodiments the interrupt request signal indicates an expiry of a frame time period, for example that a frame number change has occurred. In some embodiments the interrupt request signal is provided by interrupt logic, for example the interrupt logic of the circuitry of FIG. 1. Upon receipt of the interrupt request signal, the process proceeds to block 313. In some embodiments, however, the process first reads a frame number, as discussed below with respect to block 315, prior to proceeding to block 313.

In block 313 the process reads an indication of current provided to a load. In some embodiments the indication of current provide to the load is read from a current metering register. The current metering register, in some embodiments, is a register, or other memory or storage element(s) storing the indication of current provided to the load. The indication of current stored in the current metering register may be modified over time, for example to reflect changes in current provided to the load. In some embodiment the indication of current provided to the load and/or the current metering register are as discussed with respect to FIG. 1.

In block 315 the process reads a frame number. In some embodiments the frame number is read from a frame number register. The frame number is indicative of a time. The frame number register is a register, or other memory or storage element(s) storing the frame number. The frame number stored in the frame number register, for example, may be modified over time, for example to indicate a passage of time. In some embodiments the frame number and the frame number register are as discussed with respect to FIG. 1.

In optional block 317 (used in some embodiments) the process compares the frame number read in block 315 with the frame number read in block 313. If they differ, the process proceeds back to block 313 (and may skip optional block 317), otherwise the process continues to block 319.

In block 319 the process associates the indication of current provided to the load, read in block 213, with the frame number read in block 315, and stores such information. In various embodiments the process may stores the indication of current and frame number in a table, for example, or in some other data structure.

In optional block 321, the process clears the interrupt request signal, and thereafter returns to block 311.

In some embodiments the frame boundary is determined within 10 ns accuracy by a clock which is typically 100 MHz or higher.

In some embodiments the voltage regulator block can also capture temperature sensor measurements corresponding to a same frame number as current measurements. This may provide a very accurate delay of a temperature profile compared to a current profile. Even if a CPU, for example a host processor samples this data at varying time intervals every few milliseconds the current-temperature data pair would be synchronized within 10 ns with respect to each other in time.

In embodiments in which the voltage regulator is on the same silicon as the load, there can be multiple temperature sensors measurements captured as a data set corresponding to the same frame number representing the temperature profile of the silicon. If the voltage regulator is on a separate silicon within the same package as the load, for example a processor of a system-on-chip (SoC) this would represent the temperature profile of a SiP (system-in-package).

In some embodiments the frame based data set is expanded to include one, some, or all of the following: voltage monitor comparator signals (for example used by a voltage regulator, or as used by transient control circuitry, or otherwise), control signals from host processor, for example such as dynamic voltage control (DVC) signals, and/or Alarm and/or interrupt signals. Such information within the data set would, in many embodiments, be synchronized very accurately based on the frame boundary, and can be sampled at varying time intervals by a host processor without losing the accuracy of the profile.

In some embodiments each data set for a frame represents 1 us intervals with 10 ns accuracy. When a significant event occurs such as receiving a DVC instruction from an SoC, a data set including the DVC instruction may be stored within in register in or associated with the voltage regulator block along with the frame number. The next time the SoC requests information (polling or interrupt) the stored frame number(s) and data set(s) are available together with the current frame number and dataset. The frame numbers provide a very accurate time delay information between the current data set and when the significant event occurred. Accordingly, the host processor, which may be the SoC, can collect multiple samples at varying time intervals and still obtain very accurate time delays between the current data set and all the significant events since the last sample. Statistical information from multiple samples may therefore be analyzed with respect to the significant event of interest very accurately in time.

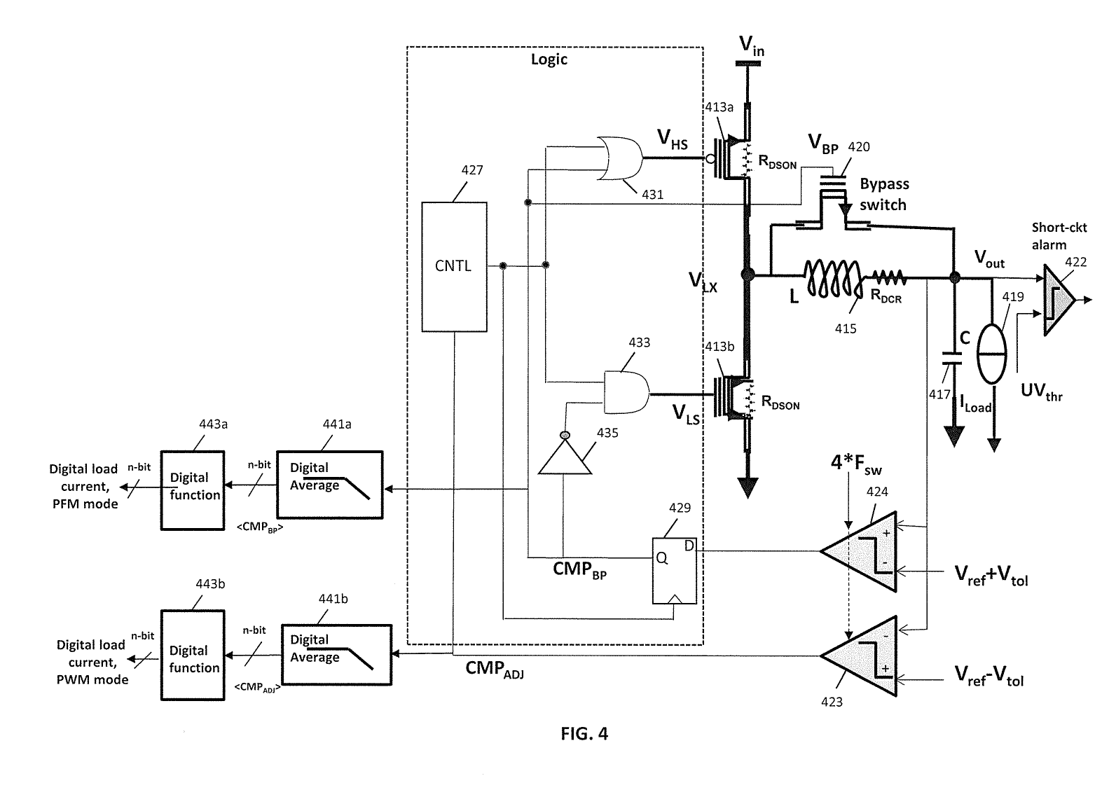

For completeness, FIG. 4 is a semi-schematic, semi-block diagram of a voltage regulator including example current metering circuitry. The voltage regulator includes circuitry, digital circuitry in various embodiments, for determining an indication of load current supplied to a load. The indication of load current may be useful in many respects, including in operation of the voltage regulator, in determining if an over current situation exists, and in allowing for improved thermal management. In various embodiments the circuitry includes circuitry for determining whether an output voltage of the voltage regulator is above and/or below a predefined range of voltages, for determining an average of such occurrences, and for determining an indication of load current based on the average of such occurrences.

As illustrated in FIG. 4, the voltage regulator includes a high side switch 413a, a low side switch 413b, a bypass switch 420 (optional), an output inductor 415, an output capacitor 417, a logic circuitry 421 for controlling the high side, low side, and bypass switches, a first comparator 423, a second comparator 424, a third comparator 422, a first digital average block 441a, a second digital average block 441b, a first digital function block 443a, and a second digital function block 443b.

The voltage regulator of FIG. 4 operates the high side, low side, and bypass switches so as to regulate voltage applied to a load 419. In doing so, the voltage regulator operates the high side and low side switches to provide regulated voltage to the load, and in various embodiments, or at various times, the switches may be operated in a pulse width mode (PWM) or a pulse frequency mode (PFM). The voltage regulator also operates the bypass switch, also optimal in many embodiments, in accordance with an output provided by the second comparator 424 indicating whether the output voltage of the converter is above a predetermined magnitude.

Outputs of each of the comparators are also provided to the first digital average block 441a and the second digital average block 441b, respectively. The digital averages are provided to the first digital function block 443a and the second digital function block 443b, respectively, which determine an indication of load current. In some embodiments, the indication of load current may be provided to a current metering register, for example the current metering register of FIG. 1.

Referring to FIG. 4, the high side switch 413a and the low side switch 413b are coupled in series between a first voltage source and a second voltage source. The first voltage source is at a higher voltage than the second voltage source, with the high side switch coupling the first voltage source to the low side switch, and the low side switch coupling the second voltage source to the high side switch. The high side and low side switches may be formed, for example, with metal-oxide-semiconductor field-effect transistor (MOSFET) transistors, with a p-channel MOS transistor forming the high side switch and an n-channel MOS transistor forming the low side switch. In operation, either the high side switch is active, the low side switch is active, or neither switch is active. For illustrative purposes, the high side and low side switches also show a resistance (R_{DSON}) provided by the switches.

The output inductor 415 has one end coupled to a node between the high side switch 413a and the low side switch 413b, and also to a first end of the bypass switch 420. Another end of the output inductor is coupled to the output capacitor 417, a second end of the bypass switch 420, and the load 419, with the load current I_{Load} passing through the load. A node coupling the other end of the output inductor, the output capacitor, and the load generally may be considered the output of the voltage regulator. For illustrative purposes, the other end of the output inductor 415 also shows a resistance (R_{DCR}) provided by the output inductor and associated circuit paths, e.g., a parasitic effect.

The first comparator 423, the second comparator 424, and the third comparator 422 generally have a first input coupled to the output node, their second inputs coupled to reference voltages, and the comparators configured to determine which input is greater. With respect to the first comparator 423, the reference voltage, for example, may be a desired output voltage of the voltage regulator minus a tolerance voltage. The first comparator therefore determines whether the output voltage of the voltage regulator is less than or greater than a desired output voltage minus a tolerance voltage. With respect to the second comparator 424, the reference voltage may be the desired output voltage of the voltage regulator plus a tolerance voltage. The second comparator therefore determines whether the output voltage of the voltage regulator is greater than or less than the desired output voltage plus the tolerance voltage. With respect to the third comparator 422, the reference voltage may be a minimum operational voltage for the voltage regulator. The third comparator therefore determines whether the output voltage of the voltage regulator drops below the minimum operational voltage. Operations below the minimum operational voltage generally indicates a short circuit, and an output of the third comparator is may be provided to a short-circuit alarm to prevent a device from operating under conditions indicating a short circuit situation.

The logic circuitry 421 may receive the output signals from the first and second comparators to control states of the high side, low side, and bypass switches. The logic circuitry 421 generally controls the states of the high side, low side, and bypass switches by way of producing control signals for controlling those switches.

As shown in FIG. 4, a latch 429 stores the signal produced by the second comparator 424. The latch stores the signal when an output of the multiplexer, indicating an end of the duty cycle of the converter switches, transitions to a high state. An output of the latch (which may be referred to as CMP_{BP}) is provided to a gate of the bypass switch, an OR gate 431 and, after passing through an inverter 435, to an AND gate 433. The OR gate also receives the output of the multiplexer, and provides an output to a gate of the high side switch. The high side switch, active when its gate input is low, is therefore active when both the output of the multiplexer and the output of the latch are low. The AND gate also receives the output of the multiplexer, and provides an output to a gate of the low side switch. The low side switch, active when its gate input is high, is therefore active when the inverted latch output is high and the output of the multiplexer is high.

As further shown in FIG. 4, the first digital average block 441a receives the output (CMP_{BP}) of the latch 429. In various embodiments, the first digital average block monitors the output CMP_{BP} by way of recording the output CMP_{BP} over a period of time, and generates a digital average (which may be referred to as <CMP_{BP}>) of the output CMP_{BP} based on recorded values of the output CMP_{BP}. The first digital logic block 443a, in various embodiments, receives the digital average <CMP_{BP}> from the first digital average block, and determines and outputs a first digital load current based on the digital average <CMP_{BP}>. The digital average <CMP_{BP}> may be considered a function of load current, a converter input voltage, the desired output voltage of the voltage regulator, an inductance value of the output inductor, and a period of a switching frequency of the voltage regulator. In some embodiments a correlation of <CMP_{BP}> and load current is determined based on voltage regulator topology. In some embodiments the correlation of <CMP_{BP}> and load current is determined based on simulation and/or measurement of voltage regulator operation under various load conditions. In some embodiments, <CMP_{BP}> may be considered to be related to load current by a first order equation, for example of the form <CMP_{BP}>=mI_{Load}+b.

Similarly, the second digital average block 441b receives the output (CMP_{ADJ}) of the first comparator 423. In various embodiments, the second digital average block monitors the output CMP_{ADJ} by way of recording the output CMP_{ADJ} over a period of time, and generates a digital average (which may be referred to as <CMP_{ADJ}>) of the output CMP_{ADJ} based on recorded values of the output CMP_{ADJ}. The second digital logic block 443b, in various embodiments, receives the digital average <CMP_{ADJ}> from the second digital average block, and determines and outputs a second digital load current based on the digital average <CMP_{ADJ}>. The digital average <CMP_{ADJ}> may be considered a function of the second digital load current, the bias voltage, the voltage offset, and a parasitic resistance (for example of the switches and output inductor) of the voltage regulator.

Although the invention has been discussed with respect to various embodiments, it should be recognized that the invention comprises the novel and non-obvious claims supported by this disclosure.

What is claimed is:

1. A method of providing voltage regulator time aware output current indications to a host processor, comprising:
determining an indication of voltage regulator output current;
determining a period of time during which the indication of voltage regulator output current was determined;
storing in memory of the voltage regulator the indication of voltage regulator output current in association with an indication of the period of time during which the indication of voltage regulator output current was determined; and
providing to the host processor the indication of voltage regulator output current and the indication of the period of time during which the indication of voltage regulator output current was determined.

2. The method of claim 1, wherein the indication of the period of time comprises a frame number.

3. The method of claim 2, wherein the frame number changes periodically at a first rate, and determining the indication of voltage regulator output current occurs at a second rate, the second rate faster than the first rate.

4. The method of claim 3, further comprising storing the frame number in memory of the voltage regulator.

5. The method of claim 4, wherein determining the period of time during which the indication of voltage regulator output current was determined comprises:
reading the frame number stored in the memory before determining the indication of voltage regulator output current;
reading the frame number stored in the memory after determining the indication of voltage regulator output current; and
determining if the frame number read before determining the indication of voltage regulator output current is the same as the frame number read after determining the indication of voltage regulator output current.

6. The method of claim 1, wherein the indication of voltage regulator output current comprises an indication of a moving average of voltage regulator output current.

7. The method of claim 1, further comprising receiving an indication of temperature and storing the indication of temperature in association with the indication of the period of time during which the indication of voltage regulator output current was determined.

8. The method of claim 1, further comprising receiving a control signal from the host processor and storing an indication of the control signal from the host processor in association with the indication of the period of time during which the indication of voltage regulator output current was determined.

9. The method of claim 1, wherein the period of time has a duration of a predetermined number of clock cycles of a clock signal for the voltage regulator.

10. A system for providing to a host processor an indication of an output current of a voltage regulator supplied to a load, the system comprising:
a current meter configured to determine an indication of the output current of the voltage regulator supplied to a load;
a current register configured to store the indication of the output current, the current register readable by the host processor;
a counter to count a number of cycles of a clock signal of a voltage regulator at which a frame number for the voltage regulator should be incremented; and
a frame number register configured to store the frame number of a frame associated with the indication of the output current, the frame number register readable by the host processor.

11. The system of claim 10 further comprising:
interrupt logic configured to generate an interrupt signal upon a change in frame number.

12. The system of claim 10 wherein the indication of the output current is an average of the output current applied to the load over a predetermined period of time.

13. The system of claim 10 wherein the indication of the output current applied to the load is a measurement of the output current at a specific time.
